(19) United States
(12) Patent Application Publication
(10) Pub. No.: US 2006/0175623 A1
(43) Pub. Date: Aug. 10, 2006

(54) Light-source apparatus and image display apparatus

(75) Inventor: Yoichi Kimura, Tokyo (JP)

Correspondence Address: VOLPE AND KOENIG, P.C., UNITED PLAZA, SUITE 1600, 30 SOUTH 17TH STREET, PHILADELPHIA, PA, 19103, US

(73) Assignee: OLYMPUS CORPORATION, Tokyo (JP)

(21) Appl. No.: 11/290,112

(22) Filed: Nov. 30, 2005

(30) Foreign Application Priority Data
Dec. 3, 2004 (JP) 2004-351574

(51) Int. Cl. H01L 33/00

(52) U.S. Cl. 257/91

(57) ABSTRACT

The present invention provides an image display apparatus including a light-source apparatus and a light-source apparatus in which a plurality of light-emitting devices are uniformly cooled to prevent any variation in brightness. The light-source apparatus includes a plurality of light-emitting devices for emitting illumination light, a holding member for holding the plurality of light-emitting devices, and a duct disposed adjacent to the holding member and in which a plurality of refrigerant channels through which refrigerant flows are formed. The holding member includes at least one thermal conductor which form a common channel wall of the plurality of refrigerant channels in the duct.

### BACKGROUND OF THE INVENTION

1. Field of the Invention

The present invention relates to a light-source apparatus in which a plurality of light-emitting elements can be cooled and to an image display apparatus provided with such a light-source apparatus.

This application is based on Japanese Patent Application No. 2004-351574, the content of which is incorporated herein by reference.

2. Description of Related Art

In recent years, light-emitting devices have come into use as light sources, and they are being used as light sources in image display devices. High-brightness light sources are required for image display devices, but light-emitting devices such as LEDs cannot obtained emitted light of the required brightness in normal steady-state operation. Therefore, one method of obtaining momentarily high-brightness light emission is to flow an electrical current that exceeds the electrical current for steady-state light emission. With this method, however, since the light emission is momentary, in order to provide continuous light emission, a method in which a large number of light-emitting devices are arranged and made to emit light sequentially is used. Thus, techniques for extracting the momentary light emission in a sequential optical system have been designed. FIG. 20 is a schematic diagram of a conventional image display apparatus realizing such a technique. FIG. 21 is a top view showing a light-source apparatus in the image display apparatus shown in FIG. 20.

In the image processing apparatus shown in FIG. 20, a plurality of light-emitting devices 120 are formed of red light-emitting devices 101a, 101b, 101c, and 101d, blue light-emitting devices 102a, 102b, 102c, and 102d, and green light-emitting devices 103a, 103b, 103c, and 103d. As shown in FIG. 21, these light-emitting devices 120 are disposed on the inner surface of a cylindrical holding member 119 constituting the light-source apparatus. These light-emitting devices 120 include four red light-emitting devices, four blue light-emitting devices, and four green light-emitting devices, but the number of light-emitting devices 120 of each color is determined depending on the required intensity of the light-source apparatus and the performance of the light-emitting devices 120 of each color. To each light-emitting device 120, a voltage is applied from a power-supply control circuit 140 and a momentary electrical current having a current value that depends on the light-emission efficiency of the light-emitting devices of the respective colors is applied from a power-supply control circuit 108. Due to this momentary electrical current, each light-emitting device 120 emits momentary light. The emitted momentary light is extracted to the exterior of the light-source apparatus by rotating optical systems 115, 116, and 117, which are driven by a motor 114.

These light-emitting devices 120 use electrical power when emitting light, but any electrical power that is not used to emit light is converted into heat. When the temperature of the light-emitting devices 120 increases due to this heat, the light-emission efficiency of the light-emitting devices 120 is decreased and their lifetime is shortened; therefore, it is necessary to cool the light-emitting devices 120. Also, as shown in FIGS. 20 and 21, when a large number of light-emitting devices 120 is disposed in the holding member 119, depending on the cooling method, temperature variations may occur between the individual light-emitting devices 120, resulting in a light source whose brightness is temporally unstable, or uneven luminance may occur.

As a cooling structure for cooling a cylindrical heat source, such as that described above, as shown in FIG. 22, a cooling apparatus 130 having a construction that guides an auxiliary flow of refrigerant from the lower side has been proposed (for example, see Japanese Unexamined Patent Application Publication No. HEI-5-135869) . The cooling apparatus described in this Unexamined Patent Application guides an auxiliary flow of refrigerant at the downstream side 130b of a cylindrical body to be cooled, and the downstream side 130b is also cooled in the same way as the upstream side 130a.

However, with the cooling apparatus 130 described in the above-described Unexamined Patent Application, since an auxiliary cooling flow which is made using a main cooling flow is used, it is difficult to control the flow rate of the refrigerant. In particular, it is difficult to control the flow rate of the refrigerant with good accuracy depending on the position in the circumferential direction (hereinafter referred to as the “angular position”) of the cylindrical body 130. Therefore, it is considered extremely difficult to make the temperature difference for all angular positions of the cylindrical body 130 extremely small for cooling it. Also, with the cooling apparatus described in the above-mentioned Unexamined Patent Application, no example of a cooling structure designed for a plurality of light-emitting devices is disclosed.

### BRIEF SUMMARY OF THE INVENTION

The present invention has been conceived to overcome the problems described above, and an object thereof is to provide a light-source apparatus in which a plurality of light-emitting elements are uniformly cooled so that there is no variation in luminance, and an image display apparatus provided with such a light-source apparatus.

In order to realize the object described above, the present invention provides the following solutions.

A light-source apparatus of the present invention includes a plurality of light-emitting devices for emitting illumination light; a holding member for holding the plurality of light-emitting devices; and a duct disposed adjacent to the holding member and in which a plurality of refrigerant channels through which refrigerant flows are formed, wherein the holding member includes at least one thermal conductor forming a common channel wall of the plurality of refrigerant channels in the duct.

With the light-source apparatus according to the present invention, since the holding member includes at least one thermal conductor forming a common channel wall of the plurality of refrigerant channels in the duct, it is possible to cool the plurality of light-emitting devices, which generate heat. In other words, because the duct is disposed adjacent to the holding member, by flowing the refrigerant in each refrigerant channel, the light emitting devices held in the holding member can be uniformly cooled, the temperature rise of the light-emitting devices can be suppressed, and illumination light having no brightness variation can be obtained.

Furthermore, the light-source apparatus of the present invention may have a configuration in which a supply port through which the refrigerant is supplied and an exhaust port through which the refrigerant is discharged are provided in the duct.

With the light-source apparatus of this configuration, by providing the supply port through which refrigerant is supplied and the exhaust port through which refrigerant is discharged, the refrigerant flows without lingering in the refrigerant channels. Accordingly, heat exchange is efficiently carried out between the holding member and the refrigerant, which allows the light-emitting devices to be cooled effectively.

Furthermore, the light-source apparatus of the present invention may have a configuration in which the total amounts of heat released per unit time by the light-emitting devices that are held at each part of the holding member forming the respective channel walls of the plurality of refrigerant channels are substantially the same as each other.

With the light-source apparatus of this configuration, because the total amounts of heat released by the light-emitting devices held in each part of the holding member forming the respective channel walls of the plurality of refrigerant channels are substantially the same as each other, by flowing the refrigerant in each channel, it is possible to uniformly cool the light-emitting devices held in the holding member more effectively.

Furthermore, the light-source apparatus of the present invention may have a configuration in which the supply port and the exhaust port are thermally connected via the holding member.

With the light-source apparatus of this configuration, because the supply port and the exhaust port are thermally connected via the holding member and because the refrigerant flowing in from the supply port is readily conveyed to the exhaust port, the heat generated by the light-emitting devices held in the holding member is readily absorbed.

Furthermore, the light-source apparatus of the present invention may have a configuration in which the holding member is cylindrical, and the light-emitting devices are disposed on the inner circumferential surface of the holding member so as to emit illumination light towards a central axis of the holding member.

With the light-source apparatus of this configuration, because the light-emitting devices are disposed on the inner circumferential surface of the holding member, which is cylindrical, so as to emit illumination light towards the central axis of the holding member, the illumination light emitted from the light-emitting devices can be extracted from the central axis of the holding member to an optical system. Accordingly, the light-source apparatus having the above-described configuration can serve as a light-source apparatus in which, for example, a plurality of light-emitting devices are made to sequentially emit momentary light. In such a case, the amount of heat released by the light-emitting devices can be suppressed, and highly intense light can be obtained.

Furthermore, the light-source apparatus of the present invention may have a configuration in which the supply port and the exhaust port are formed in the wall of the duct opposite the holding member.

With the light-source apparatus of this configuration, because the supply port and the exhaust port are formed in the wall of the duct opposite the holding member, the refrigerant entering from the supply port and flowing through the refrigerant channels can be efficiently discharged from the exhaust port via the holding member.

Furthermore, the light-source apparatus of the present invention may have a configuration in which angles formed by a perpendicular descending from the supply port to the central axis of the holding member and a perpendicular descending from the exhaust port to the central axis of the holding member are equal.

With the light-source apparatus of this configuration, because the angles formed by the perpendicular descending from the supply port to the central axis of the holding member and the perpendicular descending from the exhaust port to the central axis of the holding member are equal to each other, it is possible to more easily cool the light-emitting devices more efficiently.

Furthermore, the light-source apparatus of the present invention may have a configuration in which a plurality of the supply ports are provided; and the plurality of supply ports are positioned so as to be rotationally symmetric with respect to the central axis of the holding member. Instead, or at the same time, the light-source apparatus of the present invention may have a configuration in which a plurality of the exhaust ports are provided; and the plurality of exhaust ports are positioned so as to be rotationally symmetric with respect to the central axis of the holding member.

With the light-source apparatus of this configuration, because at least the plurality of supply ports and the plurality of exhaust ports are disposed to be rotationally symmetric with respect to the central axis of the holding member, the refrigerant that absorbs the heat generated by the plurality of light-emitting devices is efficiently discharged from the exhaust ports. Therefore, by flowing the refrigerant in the refrigerant channels, the light-emitting devices can be uniformly cooled, the temperature rise of the light-emitting devices can be suppressed, and illumination light having no brightness variations can be obtained.

Furthermore, the light-source apparatus of the present invention may have a configuration in which the plurality of refrigerant channels are formed in a layered structure stacked in the direction of the central axis of the holding member, around the outer circumferential surface of the holding member; and the supply port and the exhaust port are disposed so that the respective flow directions of the refrigerant flowing in each refrigerant channel, which are adjacent to each other in the central axis direction of the holding member, are in opposite directions about the central axis of the holding member.

With the light-source apparatus of this configuration, because the plurality of refrigerant channels are formed in a layered structure stacked in the central axis direction of the holding member and the refrigerant flows from the supply ports for the respective channels, the refrigerant that absorbs the heat generated by the plurality of light-emitting devices is discharged from the exhaust ports. At this time, because the refrigerant flows in opposite (alternate) directions between each refrigerant channel, increases and decreases in the temperature rise of the refrigerant are cancelled out. Therefore, the light-emitting devices can be uniformly cooled, the temperature rise of the light-emitting devices can be suppressed, and illumination light having no brightness variations can be obtained.

Furthermore, the light-source apparatus of the present invention may have a configuration in which the plurality of refrigerant channels are formed in planes intersecting the central axis of the holding member, around the outer circumferential surface of the holding member; and the supply port and the exhaust port are disposed so that the respective flow directions of the refrigerant flowing in each refrigerant channel are in the same direction about the central axis of the holding member.

With the light-source apparatus of this configuration, because the plurality of refrigerant channels are formed in planes intersecting the central axis of the holding member and refrigerant flows from the supply ports for the respective channels so as to be in the same direction about the central axis, the refrigerant that absorbs the heat generated by the plurality of light-emitting devices is efficiently discharged from the exhaust ports. At this time, because increases and decreases in the temperature rise of the refrigerant between each refrigerant channel are cancelled out, the light-emitting devices can be uniformly cooled, the temperature rise of the light-emitting devices can be suppressed, and illumination light having no brightness variations can be obtained.

Furthermore, the light-source apparatus of the present invention may have a configuration in which a heatsink that extends inside the duct is formed in the holding member.

With the light-source apparatus of this configuration, because the heatsink that extends inside the duct is formed, and because the heat generated by the light-emitting devices is absorbed by this heatsink, it is possible to increase the heat-dissipating effect of the light-emitting devices.

An image display apparatus of the present invention, which is provided with a light-source apparatus according to any of the above-above described configurations, for displaying to an observer an image in response to input image information, includes a light-emission controller for driving and controlling the plurality of light-emitting devices in a constant-current or constant-voltage manner; an image modulation unit for modulating, in response to the image information, the illumination light emitted from the plurality of light-emitting devices driven and controlled by the light-emission controller; a display optical unit for displaying the modulated illumination light modulated in the image modulation unit so as to be observable by an observer; and a pump for supplying the refrigerant inside the refrigerant channels.

With this image display apparatus according to the invention, first, the pump is operated to feed refrigerant into the refrigerant channels. Thereafter, the spatial modulation unit is illuminated with the illumination light emitted from the light-source apparatus. Then, the projection optical unit is irradiated with the illumination light modulated in the spatial modulator unit, and a modulated image in response to the input information is projected by the projection optical unit. At this time, because the heat generated by the plurality of light-emitting devices is uniformly absorbed, the illumination light emitted by the light-source apparatus has no brightness variation, and therefore, it is possible to project a clear image that is free of luminance variations.

The present invention provides the following advantages.

In the light-source apparatus according to the present invention, because the holding member is formed of a thermal conductor, thermal exchange of the plurality of light-emitting devices, which generate heat, is possible. In other words, because at least one part of the holding member serves as a wall in the duct, by flowing refrigerant in the refrigerant channels, the temperature rise of the light-emitting devices can be suppressed and the light-emitting devices can be uniformly cooled by the thermal conductor. Therefore, it is possible to obtain illumination light having no brightness variations.

With the image display apparatus according to the present invention, because illumination light having no brightness variations can be used, as described above, it is possible to project a clear image.

### BRIEF DESCRIPTION OF THE SEVERAL VIEWS OF THE DRAWINGS

FIG. 1 is a schematic diagram showing the principal parts of an image display apparatus according to a first embodiment of the present invention.

FIG. 2 is a perspective view showing a light-source apparatus according to the first embodiment of the present invention.

FIG. 3 is a perspective view of the image display apparatus according to the first embodiment of the present invention, with an upper part of a duct removed.

FIG. 4 is a plan view showing a refrigerant channel of the light-source apparatus according to the first embodiment of the present invention.

FIG. 5 is a graph showing the temperature rise of light-emitting devices in the light-source apparatus according to the first embodiment of the present invention.

FIG. 6 is a perspective view showing a light-source apparatus according to a second embodiment of the present invention.

FIG. 7 is a perspective view showing an image display apparatus according to the second embodiment of the present invention, with an upper part of a duct removed.

FIG. 8 is a plan view showing a refrigerant channel of the light-source apparatus according to the second embodiment of the present invention.

FIG. 9 is a graph showing the temperature rise of light-emitting devices in the light-source apparatus according to the second embodiment of the present invention.

FIG. 10 is a perspective view showing a light-source apparatus according to a third embodiment of the present invention.

FIG. 11 is a sectional perspective view taken along line X-X in FIG. 10.

FIG. 12 is a plan view showing refrigerant channels in an upper duct of the light-source apparatus according to the third embodiment of the present invention.

FIG. 13 is a plan view showing refrigerant channels in a lower duct of the light-source apparatus according to the third embodiment of the present invention.

FIG. 14 is a graph showing the temperature rise of light-emitting devices in the upper duct of the light-source apparatus according to the third embodiment of the present invention.

FIG. 15 is a graph showing the temperature rise of light-emitting devices in the lower duct of the light-source apparatus according to the third embodiment of the present invention.

FIG. 16 is a graph showing the temperature rise of the light-emitting devices in the duct of the light-source apparatus according to the third embodiment of the present invention.

FIG. 17 is a perspective view showing a light-source apparatus according to a fourth embodiment of the present invention.

FIG. 18 is a plan view showing refrigerant channels of the light-source apparatus according to the fourth embodiment of the present invention.

FIG. 19 is a graph showing the temperature rise of light-emitting devices in the light-source apparatus according to the fourth embodiment of the present invention.

FIG. 20 is a schematic diagram showing an image display apparatus according to the related art.

FIG. 21 is a top view showing a light-source apparatus of the image display apparatus in FIG. 20.

FIG. 22 is a diagram depicting a cooling apparatus according to the related art.

### DETAILED DESCRIPTION OF THE INVENTION

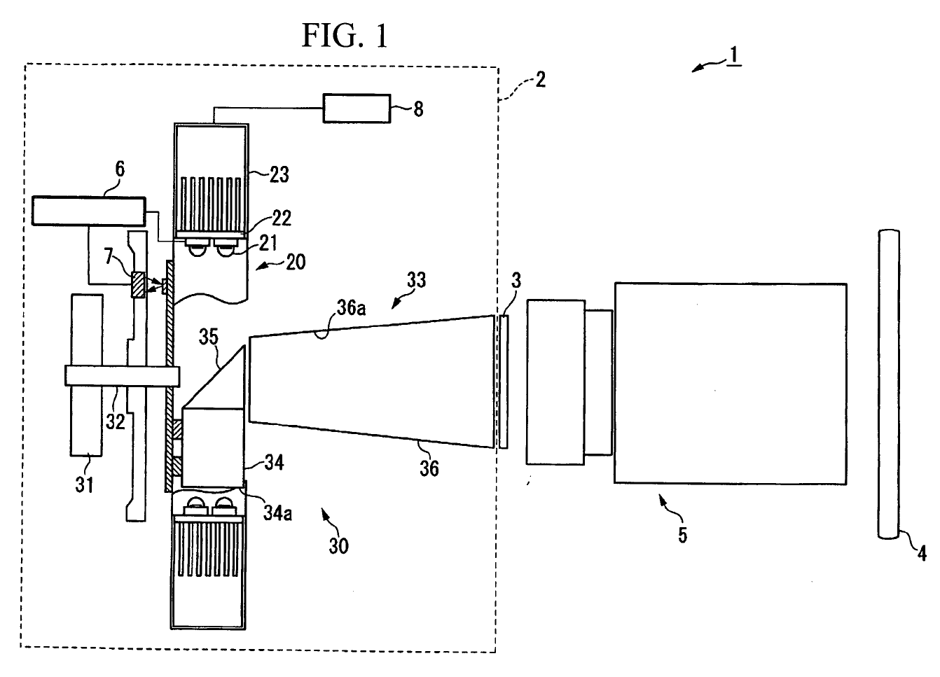

A first embodiment of the present invention will be described below with reference to FIGS. 1 to 5.

An image display apparatus 1 according to this embodiment projects an image in response to input image information so as to be viewable by an observer, and as shown in FIG. 1, includes an illumination apparatus 2 having a light-source apparatus 20 and a light-guiding unit 30, an image modulation unit 3 for modulating the illumination light emitted from the illumination apparatus 2 in response to the image information which is input, and a display optical unit 5 for projecting the image modulated in this image modulation unit 3 onto a screen 4. This screen 4 is for the observer to view a magnified projection image from the image display apparatus 1.

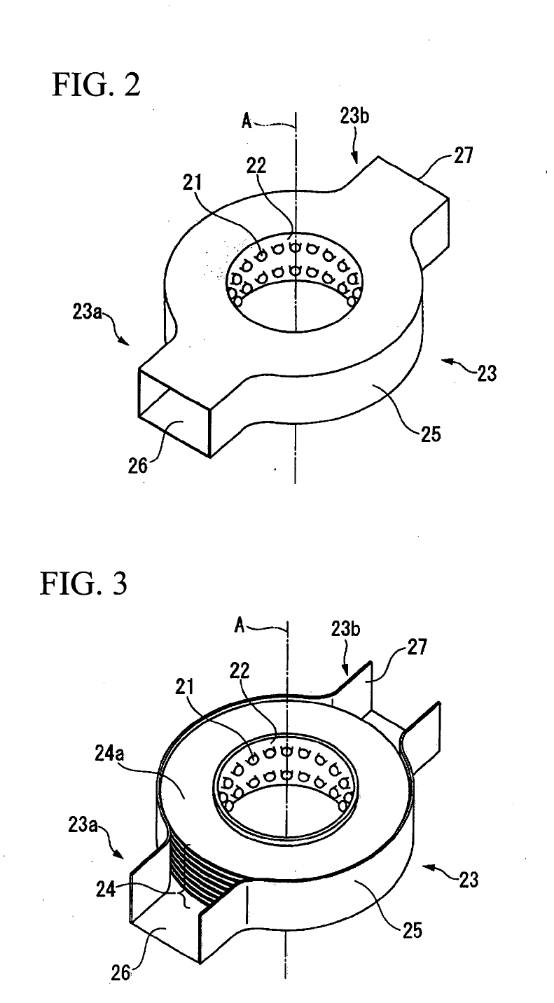

As shown in FIG. 2, the light-source apparatus 20 includes a plurality of LEDs (light-emitting devices) 21 that emit illumination light, a holding member 22 for holding the plurality of LEDs 21, and a duct 23, disposed adjacent to the holding member 22, in which are formed a plurality of refrigerant channels through which a refrigerant flows.

The holding member 22 is cylindrical, and the LEDs 21, which serve as a plurality of RGB primary-color light emitters on the inner circumferential surface, are disposed at two upper and lower stages so as to emit illumination light towards a central axis A of the holding member 22. As shown in FIG. 1, a light-emission controller 6 for controlling the driving of the LEDs 21, either in a constant-current or a constant-voltage fashion, is connected to the plurality of LEDs 21. This light-emission controller 6 controls the light-emission timing of the LEDs 21 based on a signal from a rotation sensor 7 which monitors the amount of rotation of a straight rod 34, which is described later.

The holding member 22 is formed of at least one thermally conductive member forming a common channel wall of the plurality of refrigerant channels in the duct 23; for example, it is constructed of a material having high thermal conductivity, such as copper or aluminum. Also, as shown in FIG. 3, a heatsink 24 that extends inside the duct 23 is disposed in the form of a ring on the outer circumferential surface of the holding member 22 so as to surround the outer circumferential surface of the holding member 22. This heatsink 24 is formed in the shape of sheets that extend in the radial direction of the holding member 22 and includes a plurality of fins 24a attached thereto, which are separated by constant gaps in the direction of the central axis A. These fins 24a are constructed of a material having high thermal conductivity, for example, copper or aluminum.

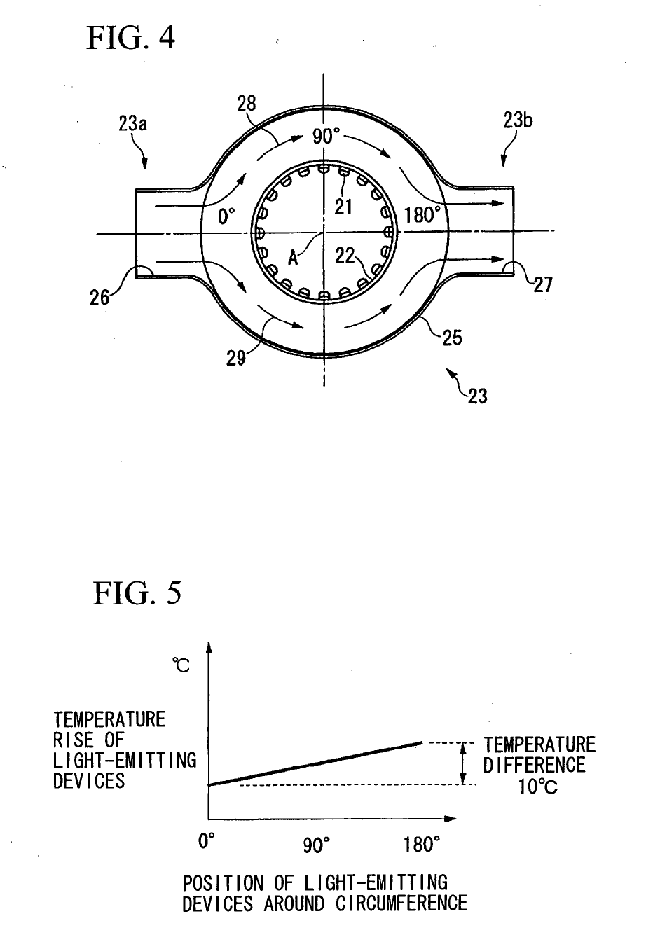

The duct 23 is disposed so that the outer circumferential wall of the holding member 22 serves as a wall thereof; this duct 23 is capable of containing the heatsink 24 in the interior thereof and is provided with a ring-shaped part 25 that is formed with an outer diameter slightly larger than the outer diameter of the fins 24a. The plurality of refrigerant channels formed in the duct 23 are formed in planes intersecting the central axis A of the holding member 22. Furthermore, a supply port 26 for supplying refrigerant is provided at one end 23a of the duct 23, and an exhaust port 27 for discharging the refrigerant supplied from the supply port 26 is provided at the other end 23b. That is, as shown in FIG. 4, the refrigerant flowing in from the supply port 26 is separated between a first channel (refrigerant channel) 28 and a second channel (refrigerant channel) 29 in the duct 23 and flows to the exhaust port 27. Therefore, the total amounts of heat released by the LEDs 21 held in the first channel 28 and the second channel 29, respectively, are substantially the same as each other.

The supply port 26 and the exhaust port 27 are thermally connected via the holding member 22. Also, as shown in FIG. 4, the supply port 26 and the exhaust port 27 are formed in the wall of the duct 23 opposite the holding member 22, and when the angular position in the circumference of the holding member 22 (hereinafter referred to as “angular position with respect to the central axis A”), whose center is defined by the central axis A, is defined such that the supply port 26 is at 0°, the exhaust port 27 is at 180°. Also, the supply port 26 and the central axis A of the holding member 22 and the exhaust port 27 and the central axis A of the holding member 22 are substantially in parallel.

Furthermore, a pump 8 for supplying refrigerant to the first channel 28 and the second channel 29 is provided at the supply port 26.

As shown in FIG. 1, the light guiding unit 30 includes a rotary motor 31, a rotation shaft 32 connected to the rotary motor 31, and a light-guiding rod 33 that can be rotated about the central axis A of the holding member 22 by the rotary motor 31. This light guiding rod 33 is disposed so that an entrance face 34a thereof faces the LEDs 21 and includes the straight rod 34 for guiding illumination light radiated from the LEDs 21 towards the central axis A, a reflecting prism 35 that deflects the illumination light emitted from the straight rod 34 by 90° and radiates it along the central axis A, and a tapered rod 36 for guiding the illumination light emitted from the reflecting prism 35 to the image modulation unit 3 side while reflecting it at a reflection surface 36a.

Next, a case in which an image is projected onto the screen 4 by the image display apparatus 1 and the illumination apparatus 2 having such a configuration will be described below.

First, when the LEDs 21 are operated, the LEDs 21 generate heat, and the heat generated by the LEDs 21 is conveyed to the holding member 22 or to the fins 24a via the holding member 22. Then, refrigerant is fed from the supply port 26 by the pump 8. Because the refrigerant entering from the supply port 26 is divided between the first channel 28 and the second channel 29, flows in the duct 23, contacts the outer circumferential surface of the holding member 22 and the fins 24a, and flows towards the exhaust port 27, it absorbs about half of the amount of heat released from the plurality of LEDs 21 in each channel. The refrigerant that has absorbed the heat is recombined and discharged from the exhaust port 27. At this time, the temperature rise of the LEDs 21 disposed on the inner circumferential surface of the holding member 22 is as shown in FIG. 5, where the angular position of the LEDs 21 is shown on the horizontal axis and the temperature rise value of the light-emitting devices at each position is shown on the vertical axis.

Simultaneously with the operation of the LEDs 21, the rotary motor 31 is operated to rotate the light-guiding rod 33. At this time, the amount of rotation of the straight rod 34 is monitored by the rotation sensor 7, and the emission timing is controlled by the light-emission controller 6 based on the monitored signal. Here, only the LEDs 21 facing the entrance face 34a of the straight rod 34 are made to emit pulsed light by the light-emission controller 6. Therefore, by continuously emitting light from sequential LEDs 21 according to the rotation of the light-guiding rod 33, in effect, highly intense light can be continuously extracted from the exit face of the tapered rod 36 even though all of the LEDs 21 are not illuminated continuously.

Then, the illumination light emitted from each LED 21 is guided by the straight rod 34 and the reflecting prism 35, repeatedly undergoes total reflection at the reflecting surface 36a of the tapered rod 36, and illuminates the image modulation unit 3.

Thereafter, the image modulation unit 3 modulates the light in response to an input image and makes the illumination light incident on a display optical unit 5 with an appropriate timing. Therefore, an optimal image is incident on the display optical unit 5. Then, this image is projected onto the screen 4 by the display optical unit 5.

With the image display apparatus 1 and the light-source apparatus 20 according to this embodiment, since the holding member 22 is formed of a thermal conductor, the plurality of LEDs 21, which emit heat, can be cooled. In other words, since the duct 23 is disposed adjacent to the holding member 22, by flowing refrigerant through the refrigerant channels, the LEDs 21 can be uniformly cooled, the rise in temperature of the LEDs can be suppressed, and illumination light having no brightness variations can be obtained. Furthermore, as shown in FIG. 5, the difference between the temperature rise value of the LEDs 21 at the supply port 26 side (at an angular position of 0°) and the temperature rise value of the LEDs at the exhaust port 27 side (at an angular position of 90°) can be kept at 10° C. or less, and the LEDs 21 can thus be uniformly cooled. Furthermore, because illumination light having no brightness variations can be used, it is possible to project a more clear image.

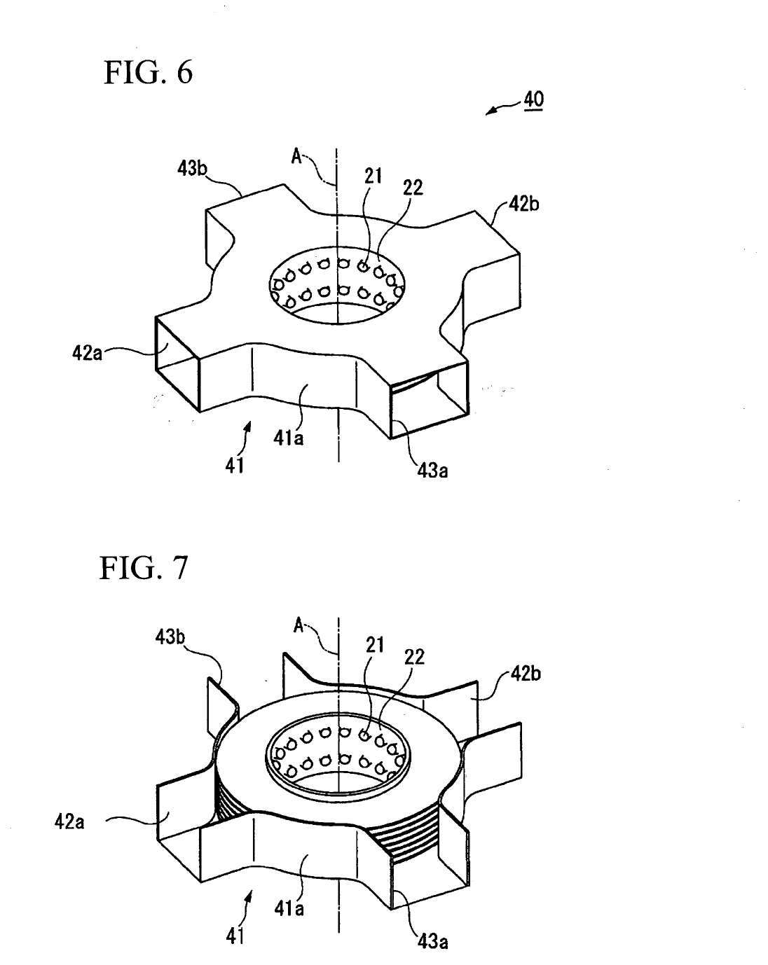

Next, a second embodiment according to the present invention will be described with reference to FIGS. 6 to 9. In each of the embodiments described below, the same reference numerals are assigned to parts having the same configuration as those in the image display apparatus 1 and the light-source apparatus 20 according to the first embodiment described above, and description thereof shall thus be omitted.

In a light-source apparatus 40 according to this embodiment, the shape of a duct 41 in the second embodiment differs from the first embodiment.

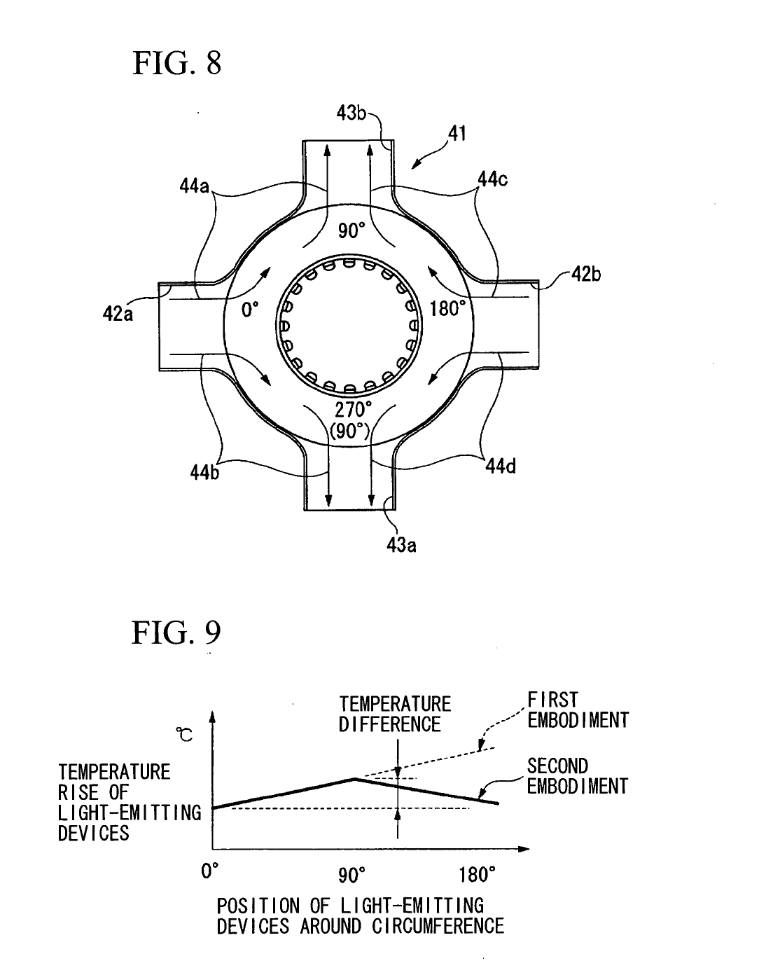

As shown in FIGS. 6 and 7, the duct 41 has projecting parts in four mutually intersecting directions (cross-shaped) of the wall, and supply ports 42a and 42b and exhaust ports 43a and 43b, which are continuous with the refrigerant channels through which the refrigerant flows, are formed in these projecting parts. The supply ports 42a and 42b are disposed so as to be 180-degrees rotationally symmetric with respect to the central axis A of the holding member 22. Also, the exhaust ports 43a and 43b are disposed so as to 180-degrees rotationally symmetric with respect to the central axis A of the holding member 22. In other words, as shown in FIG. 8, the angular positions with respect to the central axis A are at 0° and 180° for the supply ports 42a and 42b, respectively, and at 90° and 270° (90°) for the exhaust ports 43a and 43b, respectively. Therefore, the angles formed by the perpendiculars descending from the supply ports 42a and 42b to the central axis A of the holding member 22 and the perpendiculars descending from the exhaust ports 43a and 43b to the central axis A of the holding member 22 are equal.

The supply ports 42a and 42b are disposed on a straight line intersecting the central axis A of the holding member 22, and the exhaust ports 43a and 43b are disposed on a straight line intersecting the central axis A of the holding member 22 and the supply ports 42a and 42b. In other words, the refrigerant flowing in from the supply port 42a is divided between a third channel (refrigerant channel) 44a and a fourth channel (refrigerant channel) 44b of a ring-shaped part 41a and flows to the exhaust ports 43a and 43b, and the refrigerant flowing in from the supply port 42b is divided between a fifth channel (refrigerant channel) 44c and a sixth channel (refrigerant channel) 44d of the ring-shaped part 41a and flows to the exhaust ports 43a and 43b.

Next, a case in which an image is projected onto the screen 4 using the image display apparatus 1 and the light-source apparatus 40 having such a configuration will be described below.

First, when the LEDs 21 are operated, similarly to the first embodiment, refrigerant is fed from the supply ports by the pump 8. The refrigerant entering from the supply port 42a is divided between the third channel 44a and the fourth channel 44b and flows inside the duct 41, the refrigerant entering from the supply port 42b is divided between the fifth channel 44c and the sixth channel 44d and flows inside the duct 41, and the refrigerant makes contact with the outer circumferential surface of the holding member 22 and the fins 24a and flows towards the exhaust ports. Therefore, one quarter of the amount of heat generated by the plurality of LEDs 21 is absorbed in each channel. After absorbing the heat, the refrigerant flowing through the third channel 44a and that flowing through the fifth channel 44c are combined and are discharged from the exhaust port 43b, and the refrigerant flowing through the fourth channel 44b and that flowing through the sixth channel 44d are combined and discharged from the exhaust port 43a . At this time, the temperature rise of the LEDs 21 disposed on the inner circumferential surface of the holding member 22 is as shown in FIG. 9, where the angular position of the LEDs 21 is shown on the horizontal axis and the temperature rise value of the light-emitting devices at each position is shown on the vertical axis.

Thereafter, similarly to the first embodiment, the illumination light radiated from the LEDs 21 passes through the light-guiding unit 30 and an image is projected onto the screen 4.

In the image display apparatus 1 and the light-source apparatus 40 according to this embodiment, the supply ports 42a and 42b are disposed to be 180-degrees rotationally symmetric with respect to the central axis A of the holding member 22. Similarly, the exhaust ports 43a and 43b are disposed to be 180-degrees rotationally symmetric with respect to the central axis A of the holding member 22. Therefore, the refrigerant that has absorbed the heat generated by the plurality of LEDs 21 is efficiently discharged from the exhaust ports 43a and 43b. Accordingly, by flowing refrigerant from the supply ports 42a and 42b, the LEDs 21 can be uniformly cooled, the temperature rise of the LEDs 21 can be suppressed, and illumination light with no variation in brightness can be obtained. Also, as shown in FIG. 9, at angular positions from 0° to 90° with respect to the central axis A, the difference in temperature rise values of the LEDs 21 can be kept at 8° C. or lower, and the LEDs 21 can thus be more uniformly cooled compared to the first embodiment. Furthermore, since illumination light having no brightness variations can be used, a more clear image can be projected.

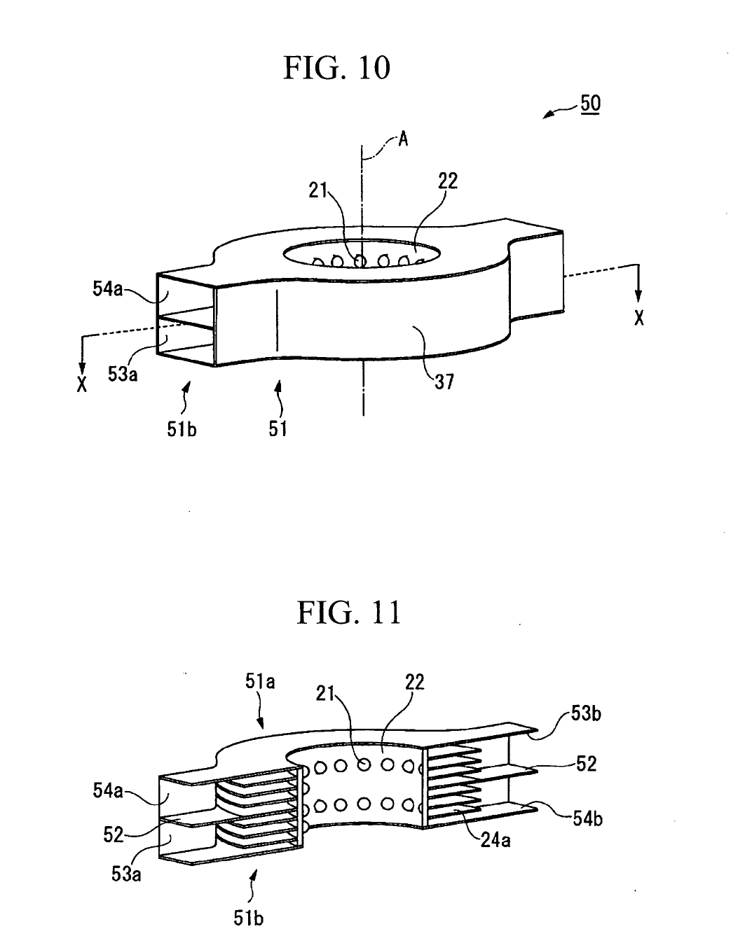

Next, a third embodiment according to the present invention will be described with reference to FIGS. 10 to 16.

In a light-source apparatus 50 according to this embodiment, the shape of a duct 51 in the third embodiment differs from that in the first embodiment.

As shown in FIGS. 10 and 11, a plurality of refrigerant channels formed in the duct 51 are formed in a layered structure stacked in the direction of the central axis A of the holding member 22, around the outer circumferential surface of the holding member 22. In other words, the duct 51 is divided into two parts, that is, upper and lower parts, in the direction of the central axis A of the holding member 22 by a partition 52 to provide an upper duct 51a and a lower duct 51b.

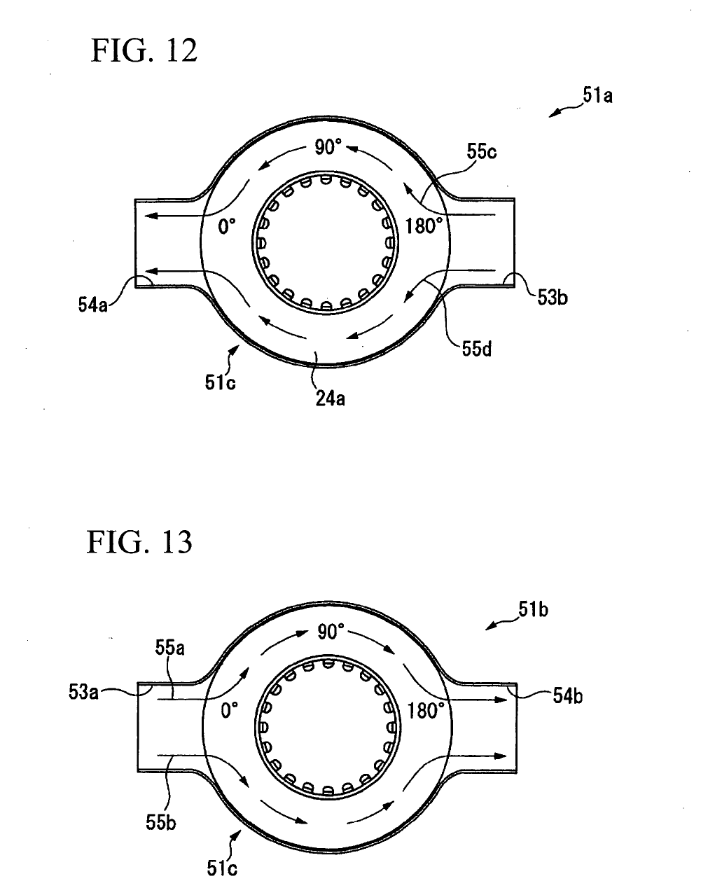

A lower supply port 53a and an upper exhaust port 54a are provided at one end of this duct 51, and a lower exhaust port 54b and an upper supply port 53b are provided at the other end thereof. In this way, the upper exhaust port 54a and the lower supply port 53a at the one end are disposed at an angular position of 0° with respect to the central axis A, and the lower exhaust port 54b and the lower supply port 53b at the other end are disposed at an angular position of 180°. In other words, as shown in FIG. 13, the refrigerant flowing in from the lower supply port 53a is divided between a seventh channel (refrigerant channel) 55a and an eighth channel (refrigerant channel) 55b in a ring-shaped part 51c and flows to the lower exhaust port 54b, and as shown in FIG. 12, the refrigerant flowing in from the upper supply port 53b is divided between a ninth channel (refrigerant channel) 55c and a tenth channel (refrigerant channel) 55d in the ring-shaped part 51c and flows to the upper exhaust port 54a. Therefore, the lower supply port 53a, the upper supply port 53b, the upper exhaust port 54a, and the lower exhaust port 54b are arranged such that the directions of flow of the refrigerant flowing through the seventh channel 55a and the ninth channel 55c are in opposite (alternate) directions around the central axis A of the holding member 22, and the directions of flow of refrigerant flowing through the eighth channel 55b and the tenth channel 55d are in opposite (alternate) directions around the central axis A of the holding member 22.

Next, a case in which an image is projected onto the screen 4 by the image display apparatus 1 and the light-source apparatus 50 having such a configuration will be described below.

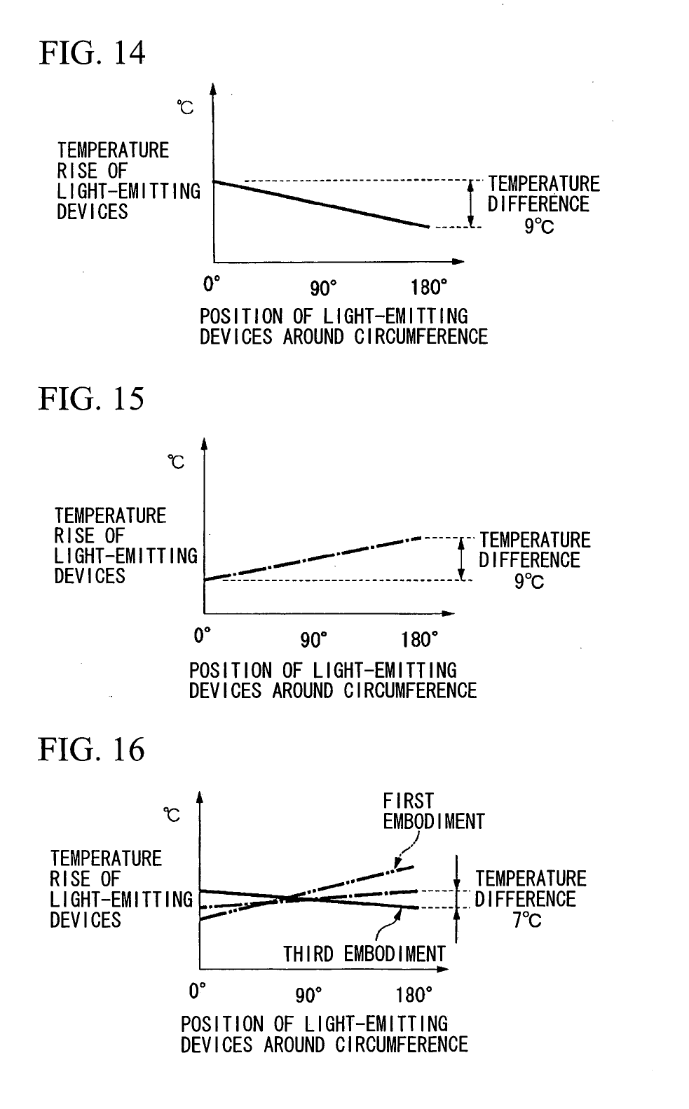

First, when the LEDs 21 are operated, similarly to the first embodiment, refrigerant is fed from the upper supply port 53b and the lower supply port 53a by a pump 8. The refrigerant entering from the lower supply port 53a is divided between the seventh channel 55a and the eighth channel 55b and flows in the duct, the refrigerant entering from the upper supply port 53b is divided between the ninth channel 55c and the tenth channel 55d and flows inside the duct, and the refrigerant makes contact with the outer circumferential surface of the holding member 22 and the fins 24a and is directed towards the lower exhaust port 54b and the upper exhaust port 54a, respectively. Therefore, one quarter of the amount of heat released by the plurality of LEDs 21 is absorbed in each channel. Thus, the refrigerant that absorbs heat and passes through the seventh channel 55a and the eighth channel 55b is combined and discharged from the lower exhaust port 54b, and the refrigerant that absorbs heat and passes through the ninth channel 55c and the tenth channel 55d is combined and discharged from the upper exhaust port 54a. The temperature rise of the LEDs 21 disposed on the inner circumferential surface of the holding member 22 at this time is as shown in FIGS. 14, 15, and 16, in which the angular position of the LEDs 21 is shown on the horizontal axes and the temperature rise of the light-emitting devices at each position is shown on the vertical axes.

Thereafter, similarly to the first embodiment, the illumination light radiated from the LEDs 21 passes through the light guiding unit 30, and an image is projected onto the screen 4.

With the image display apparatus 1 and the light-source apparatus 50 according to this embodiment, since the refrigerant flows in opposite directions in upper and lower channels which are separated in direction of the central axis A of the holding member 22 by the partition 52, the refrigerant that has absorbed the heat generated by the plurality of LEDs 21 is efficiently discharged from the upper exhaust port 54a and the lower exhaust port 54b. Therefore, by flowing the refrigerant in the refrigerant channels, the LEDs 21 can be uniformly cooled, the temperature rise of the LEDs 21 can be suppressed, and illumination light having no brightness variations can be obtained.

Furthermore, regarding the temperature rise of the LEDs 21 in the upper duct 51a, as shown in FIG. 14, at angular positions from 0° to 180° with respect to the central axis A, the temperature rise value of the LEDs 21 in the vicinity of the upper supply port 53b (close to the angular position of 180°), where the refrigerant initially flows, is small; however, the temperature of the refrigerant rises as heat is absorbed, and the temperature rise value of the LEDs 21 in the vicinity of the upper exhaust port 54a (close to the angular position of 0°), where warm refrigerant passes, is large. Nevertheless, the difference in temperature rise values of the LEDs 21 can be kept at 9° C. or lower.

Furthermore, regarding the temperature of the LEDs 21 in the lower duct 51b, at angular positions from 0° C. to 180° C. with respect to the central axis A, as shown in FIG. 15, the temperature rise of the LEDs 21 in the vicinity of the lower supply port 53a (close to the angular position of 0°) where the refrigerant initially flows is small; however, the temperature of the refrigerant rises as heat is absorbed, and the temperature rise of the LEDs 21 in the vicinity of the lower exhaust port 54b (at the angular position of 180° C.) where warm refrigerant passes, is large. Nevertheless, the difference in temperature rise of the LEDs 21 can be kept at 9° C. or lower.

Because the plurality of refrigerant channels are disposed around the outer circumferential surface of the holding member 22, which is made of a thermal conductor, increases and decreases in temperature between the upper duct 51a and the lower duct 51b cancel each other out, and as a result, the difference in temperature rise values of the LEDs 21 at angular positions from 0° to 180° is reduced compared to the first embodiment, as shown in FIG. 16. Therefore, it is possible to cool the LEDs 21 more uniformly than in the first embodiment. Also, since illumination light having no brightness variations can be used, it is possible to project a more clear image.

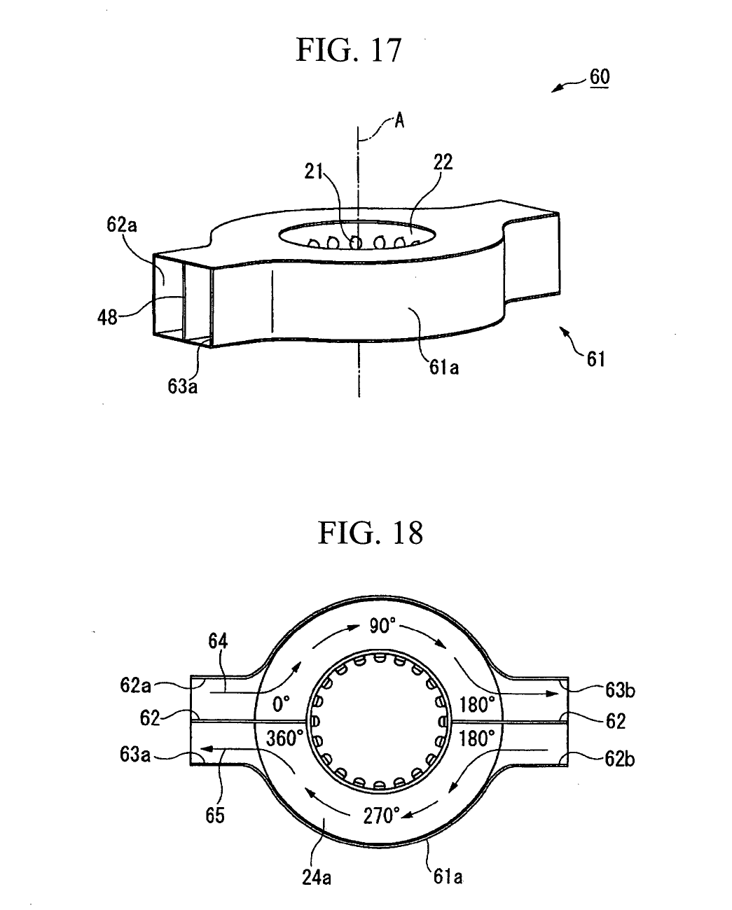

Next, a fourth embodiment according to the present invention will be described with reference to FIGS. 17 to 19.

In a light-source apparatus 60 according to this embodiment, the shape of a duct 61 in the fourth embodiment is different from that in the first embodiment.

As shown in FIGS. 17 and 18, a plurality of refrigerant channels formed in the duct 61 are formed on planes intersecting the central axis A of the holding member 22, around the outer circumferential surface of the holding member 22. In other words, the duct 61 is divided by a partition 62 into two parts in a direction orthogonal to the central axis A of the holding member 22 to provide an eleventh channel (refrigerant channel) 64 and a twelfth channel (refrigerant channel) 65.

A first supply port 62a and a second exhaust port 63a are provided at one end of this duct, and a first exhaust port 63b and a second supply port 62b are provided at the other end thereof. Thus, the first supply port 62a and the second exhaust port 63a at the one end are disposed at angular positions of 360° and 0° with respect to the central axis A, and the first exhaust port 63b and the second supply port 62b at the other end are disposed at an angular position of 180°. In other words, as shown in FIG. 18, the refrigerant flowing in from the first supply port 62a passes through the eleventh channel 64 in a ring-shaped part 61a and flows to the first exhaust port 63b, and the refrigerant flowing in from the second supply port 62b passes through the twelfth channel 65 in the ring-shaped part 61a and flows to the second exhaust port 63a. Therefore, the first supply port 62a, the second supply port 62b, the first exhaust port 63b, and the second exhaust port 63a are arranged so that the directions of flow of the refrigerant flowing through the first channel 64 and the second channel 65 are in one direction about the central axis A of the holding member 22.

Next, a case in which an image is projected onto the screen 4 by the image display apparatus 1 and the light-source apparatus 60 having such a configuration will be described below.

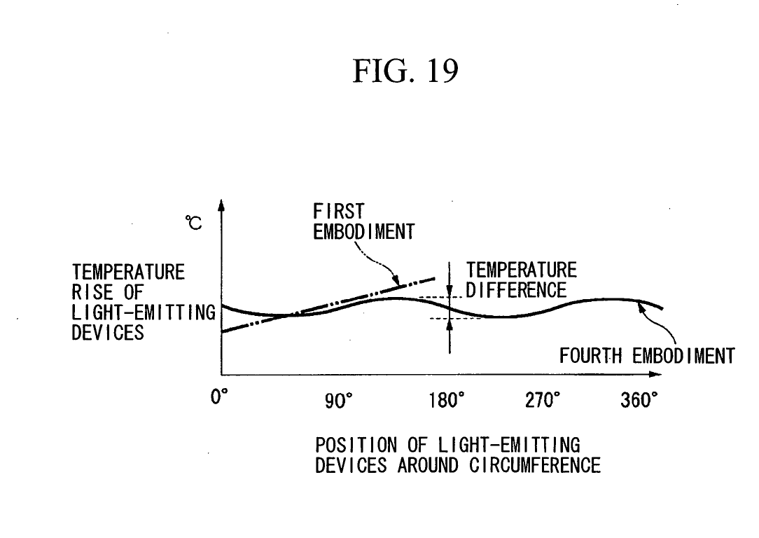

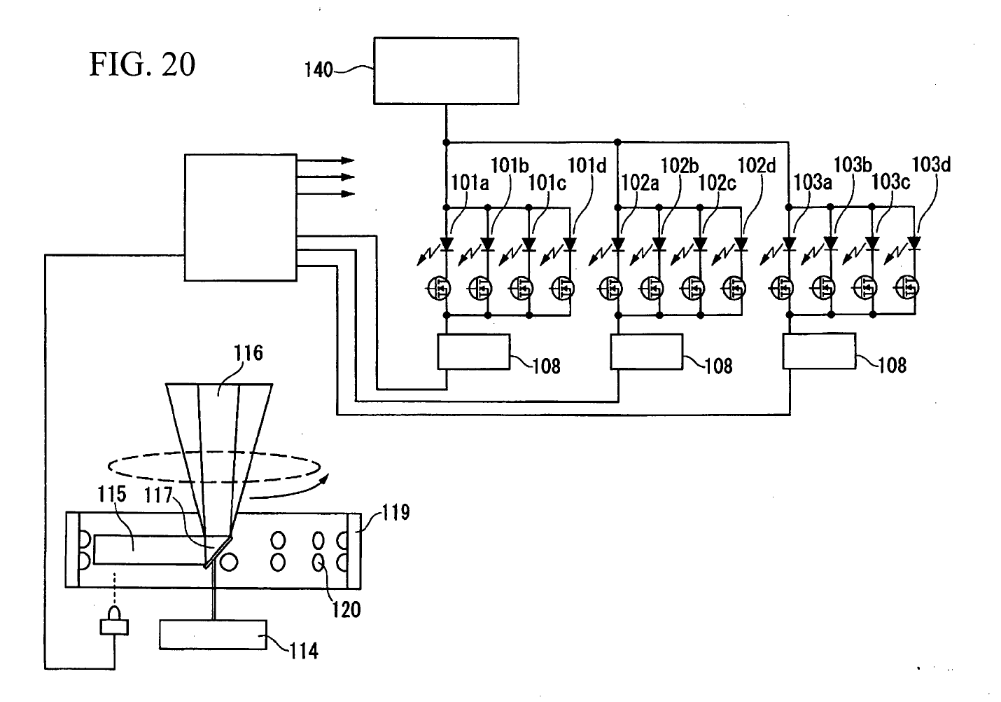

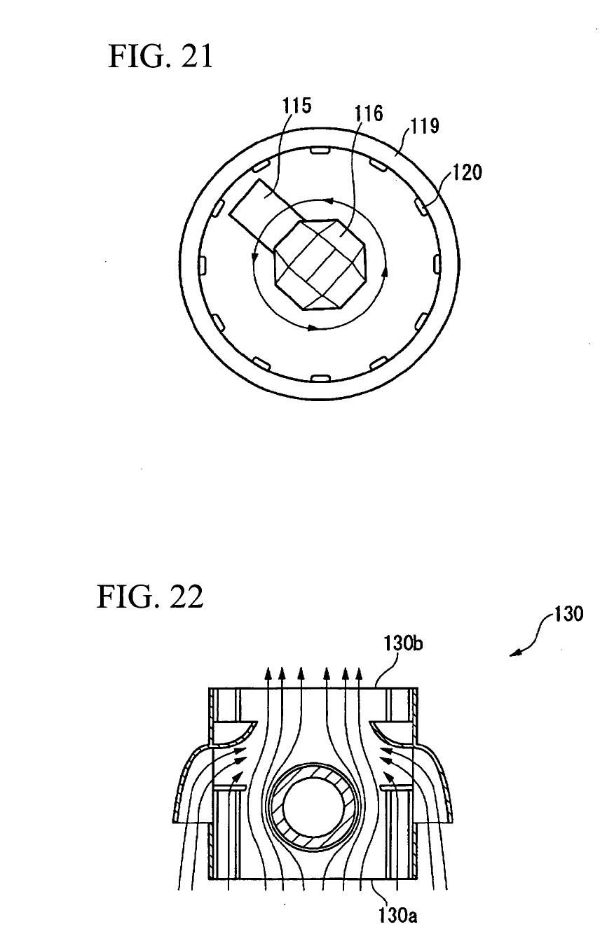

First, then the LEDs 21 are operated, refrigerant is fed from the first supply port 62a and the second supply port 62b by the pump 8. The refrigerant entering from the first supply port 62a flows through the eleventh refrigerant channel 64, the refrigerant entering from the second supply port 62b flows through the twelfth refrigerant channel 65, and the refrigerant makes contact with the outer circumferential surface of the holding member 22 and the fins 24a and is directed towards the first exhaust port 63b and the second exhaust port 63a. Therefore, half of the amount of heat generated by the plurality of LEDs 21 is absorbed in each channel. Thus, the refrigerant that absorbs the heat and passes through the eleventh channel 64 is discharged from the first exhaust port 63b, and the refrigerant that absorbs the heat and passes through the second channel 65 is discharged from the second exhaust port 63a. At this time, the rise in temperature of the LEDs 21 disposed in the inner circumferential surface of the holding member 22 is as shown in FIG. 19, where the angular position of the LEDs 21 is shown on the horizontal axis and the temperature rise value of the light-emitting devices at each position is shown on the vertical axis.

Thereafter, similarly to the first embodiment, the illumination light emitted from the LEDs 21 passes through the light guiding unit 30, and an image is projected onto the screen 4.

With the image display apparatus 1 and the light-source apparatus 60 according to this embodiment, since the refrigerant flows in opposite directions in the first channel 64 and the second channel 65, which are separated in a direction perpendicular to the central axis A of the holding member 22 by the partition 62, the refrigerant which absorbs the heat generated by the plurality of LEDs is efficiently discharged from the first exhaust port 63b and the second exhaust port 63a. Accordingly, by flowing the refrigerant through the first channel 64 and the second channel 65, the LEDs 21 can be uniformly cooled, the rise in temperature of the LEDs 21 can be suppressed, and it is possible to obtain illumination light having no intensity variations.

Also, as shown in FIG. 19, regarding the temperature of the LEDs 21 in the duct, at angular positions from 0° to 360° with respect to the central axis A, the temperature rise value of the LEDs 21 in the vicinity of the first supply port 62a (at an angular position of 0° and just before that position) and the second supply port 62b (at an angular position of 180° and just before that position), where new refrigerant flows, is small; however, the temperature of the refrigerant rises as it absorbs heat, and the temperature rise value of the LEDs 21 in the vicinity of the first exhaust port 63b (at an angular position of 180° and just before that position) and the second exhaust port 63b (at an angular position of 360° and just before that position), where warm refrigerant flows, becomes large. Nevertheless, the difference in temperature rise values of the LEDs 21 can be kept at 8° C. or lower.

Since a plurality of refrigerant channels are disposed around the outer circumferential surface of the holding member 22, which is made of a thermal conductor, increases and decreases in temperature between the eleventh channel 64 and the twelfth channel 65, which are adjacent to each other, are cancelled out, and as a result, the difference in temperature rise values of the LEDs 21 at angular positions from 0° to 360° is small compared to the first embodiment, as shown in FIG. 19. Therefore, compared to the first embodiment, the LEDs 21 can be cooled more uniformly. Furthermore, since it is possible to use illumination light having no intensity variations, a clear image can be projected.

The technical scope of the present invention is not limited to the embodiments described above; various modifications that do not depart from the spirit of the invention are possible.

For example, the diameter of the fins 24a, the thickness of the fins 24a, the material of the fins 24a, the gap between the fins 24a, the rate of flow of the refrigerant or the characteristics of a blower for blowing the refrigerant inside the duct, and the shape of the duct are set, based on experiment or numerical simulation, to suitable values for the temperature conditions and volume constraints.

Moreover, although the shape of the heatsink 24 (fins 24a) is ring-shaped, the present invention is not limited thereto; it is also possible to use another shape, so long as the same function and effects are provided. Furthermore, a duct shape combining any of the first embodiment, the second embodiment, the third embodiment, and the fourth embodiment may be used; in such a case, the same results as described above are obtained.

In addition, although the supply ports 42a and 42b are disposed to be 180-degree rotationally symmetric with respect to the central axis A of the holding member 22, and the exhaust ports 43a and 43b are disposed to be 180-degree rotationally symmetric with respect to the central axis A of the holding member 22, at least one pair from among the supply ports 42a and 42b and the exhaust port 43a and 43b may be disposed to be rotationally symmetric with respect to the central axis A of the holding member 22, and the angle of the rotational symmetry is not limited to 180 degrees. Air is preferable as the refrigerant but is not limited thereto; water or an inert fluid may also be used.

1. A light-source apparatus comprising:
a plurality of light-emitting devices for emitting illumination light;
a holding member for holding the plurality of light-emitting devices; and
a duct disposed adjacent to the holding member and in which a plurality of refrigerant channels through which refrigerant flows are formed,
wherein the holding member includes at least one thermal conductor forming a common channel wall of the plurality of refrigerant channels in the duct.

2. The light-source apparatus according to claim 1, wherein a supply port through which the refrigerant is supplied and an exhaust port through which the refrigerant is discharged are provided in the duct.

3. The light-source apparatus according to claim 1, wherein the total amounts of heat released per unit time by the light-emitting devices that are held at each part of the holding member forming the respective channel walls of the plurality of refrigerant channels are substantially the same as each other.

4. The light-source apparatus according to claim 2, wherein the supply port and the exhaust port are thermally connected via the holding member.

5. The light-source apparatus according to claim 1, wherein the holding member is cylindrical, and the light-emitting devices are disposed on the inner circumferential surface of the holding member so as to emit illumination light towards a central axis of the holding member.

6. The light-source apparatus according to claim 5, wherein the supply port and the exhaust port are formed in the wall of the duct opposite the holding member.

7. The light-source apparatus according to claim 6, wherein angles formed by a perpendicular descending from the supply port to the central axis of the holding member and a perpendicular descending from the exhaust port to the central axis of the holding member are equal.

8. The light-source apparatus according to claim 6, wherein:
a plurality of the supply ports are provided; and
the plurality of supply ports are positioned so as to be rotationally symmetric with respect to the central axis of the holding member.

9. The light-source apparatus according to claim 6, wherein:
a plurality of the exhaust ports are provided; and
the plurality of exhaust ports are positioned so as to be rotationally symmetric with respect to the central axis of the holding member.

10. The light-source apparatus according to claim 5, wherein:
the plurality of refrigerant channels are formed in a layered structure stacked in the direction of the central axis of the holding member, around the outer circumferential surface of the holding member; and
the supply port and the exhaust port are disposed so that the respective flow directions of the refrigerant flowing in each refrigerant channel, which are adjacent to each other in the central axis direction of the holding member, are in opposite directions about the central axis of the holding member.

11. The light-source apparatus according to claim 5, wherein:
the plurality of refrigerant channels are formed in planes intersecting the central axis of the holding member, around the outer circumferential surface of the holding member; and
the supply port and the exhaust port are disposed so that the respective flow directions of the refrigerant flowing in each refrigerant channel are in the same direction about the central axis of the holding member.

12. The light-source apparatus according to claim 4, wherein a heatsink that extends inside the duct is formed in the holding member.

13. An image display apparatus provided with the light-source apparatus according to claim 1, for displaying to an observer an image in response to input image information, comprising:
a light-emission controller for driving and controlling the plurality of light-emitting devices in a constant-current or constant-voltage manner;
an image modulation unit for modulating, in response to the image information, the illumination light emitted from the plurality of light-emitting devices driven and controlled by the light-emission controller;
a display optical unit for displaying the modulated illumination light modulated in the image modulation unit so as to be observable by an observer; and
a pump for supplying the refrigerant inside the refrigerant channels.

14. The light-source apparatus according to claim 3, wherein the supply port and the exhaust port are thermally connected via the holding member.

15. The light-source apparatus according to claim 14, wherein a heatsink that extends inside the duct is formed in the holding member.
